(19) United States
(12) Patent Application Publication
(10) Pub. No.: US 2025/0116613 A1
(43) Pub. Date: Apr. 10, 2025

(54) THIN FILM MONITORING METHOD AND DEVICE

(71) Applicant: Dongguk UIniveristy Industry-Academic Cooperation Foundation, Seoul (KR)

(72) Inventors: Mann Ho CHO, Seoul (KR); Jong Hoon KIM, Gimpo-si, Gyeonggi-do (KR); Kwang Sik JEONG, Seoul (KR)

(73) Assignee: UNIVERSITY-INDUSTRY FOUNDATION(UIF), YONSEI UNIVERSITY, Seoul (KR)

(21) Appl. No.: 18/833,918

(22) PCT Filed: Jan. 19, 2023
(86) PCT No.: PCT/KR2023/000934

§ 371 Date: Jul. 29, 2024

(30) Foreign Application Priority Data
Jan. 28, 2022 (KR) 10-2022-0013500

(51) Int. Cl. G01N 21/95; G01N 21/59

(52) U.S. Cl. CPC G01N 21/9501; G01N 21/59

(57) ABSTRACT

Provided is a thin film monitoring method including: injecting a laser beam into a thin film on a substrate to form excited carriers in the thin film, irradiating an electromagnetic wave onto the thin film while the excited carriers in the thin film are recombining, measuring characteristic information of the electromagnetic wave reacting with the excited carriers in the thin film, and determining composition uniformity or defect distribution of the thin film based on locations on the substrate by using a parameter including the measured characteristic information of the electromagnetic wave.

### TECHNICAL FIELD

The present invention relates to a thin film monitoring method and thin film monitoring apparatus, and more particularly, to a thin film monitoring method and thin film monitoring apparatus capable of analyzing composition uniformity or defect distribution of a thin film based on locations on a substrate in a non-contact and non-destructive manner.

### BACKGROUND ART

Semiconductor technology is evolving from patterns with a size of hundreds of nanometers to ultra-fine patterns with a size of several to tens of nanometers. As such, formation of a thin film in good quality is critical in semiconductor devices. Therefore, a thin film monitoring method and thin film monitoring apparatus capable of monitoring composition uniformity or defect distribution of a thin film based on locations on a substrate in a non-contact and non-destructive manner in a semiconductor manufacturing process needs to be developed. A related document includes Korean Patent Publication No. 10-2004-0106107.

### DETAILED DESCRIPTION OF THE INVENTION

### Technical Problem

The present invention provides a thin film monitoring method and thin film monitoring apparatus capable of monitoring composition uniformity or defect distribution of a thin film based on locations on a substrate in a non-contact and non-destructive manner.

However, the above description is an example, and the scope of the present invention is not limited thereto.

### Technical Solution

According to an aspect of the present invention, there is provided a thin film monitoring method including: injecting a laser beam into a thin film on a substrate to form excited carriers in the thin film, irradiating an electromagnetic wave onto the thin film while the excited carriers in the thin film are recombining, measuring characteristic information of the electromagnetic wave reacting with the excited carriers in the thin film, and determining composition uniformity or defect distribution of the thin film based on locations on the substrate by using a parameter including the measured characteristic information of the electromagnetic wave.

The characteristic information of the electromagnetic wave may include a transmittance or reflectance of the electromagnetic wave.

The parameter including the measured characteristic information of the electromagnetic wave may include a transmittance decay change of the electromagnetic wave over time.

The parameter including the measured characteristic information of the electromagnetic wave may include a carrier recombination time constant calculated through inverse Laplace transform on a transmittance decay function of the electromagnetic wave over time.

The carrier recombination time constant may be dividable by type of defects in the thin film and be inversely proportional to a defect density in the thin film. The carrier recombination time constant may be dividable into a first carrier recombination time constant based on a first type of defects in the thin film and a second carrier recombination time constant based on a second type of defects in the thin film. The first carrier recombination time constant may be inversely proportional to a first defect density based on the first type of defects, the second carrier recombination time constant may be inversely proportional to a second defect density based on the second type of defects, and a size relationship between the first and second carrier recombination time constants may be opposite to a size relationship between the first and second defect densities in the thin film.

The transmittance decay function of the electromagnetic wave over time may be simulatable by Equation 1.

$$\frac{Δ T}{{T}_{0}} ( t ) = {\sum }_{i = 1}^{n} {a}_{i} {e}^{- t / {τ}_{i}} \qquad ( Equation 1 )$$

(ΔT: a transmittance decay change of the electromagnetic wave, T₀: a transmittance of the electromagnetic wave when the laser beam for forming excited carriers is not injected into the thin film, n: a number of defect types in the thin film, aᵢ: a carrier recombination contribution based on each type of defects in the thin film, t: time, and τᵢ: a carrier recombination time constant based on each type of defects)

The laser beam may include a femtosecond laser beam, and the electromagnetic wave may include a terahertz wave.

The excited carriers in the thin film may include excited free electrons or holes in the thin film.

The locations on the substrate may include a center and an edge of the substrate.

According to another aspect of the present invention, there is provided a thin film monitoring apparatus including: a beam emitter for generating a beam to be injected into a thin film on a substrate to form excited carriers in the thin film, an electromagnetic wave irradiator for irradiating an electromagnetic wave onto the thin film while the excited carriers in the thin film are recombining, an electromagnetic wave receiver for receiving the electromagnetic wave transmitted through or reflected from the thin film, a measurer for measuring characteristic information of the electromagnetic wave received by the electromagnetic wave receiver, and an operation controller for determining composition uniformity or defect distribution of the thin film based on locations on the substrate by using a parameter including the measured characteristic information of the electromagnetic wave.

The electromagnetic wave irradiator may be located above the substrate, and the electromagnetic wave receiver may be located below the substrate to receive the electromagnetic wave transmitted through the thin film.

The electromagnetic wave irradiator may be located above the substrate, and the electromagnetic wave receiver may be located above the substrate to receive the electromagnetic wave reflected from the thin film.

A plurality of electromagnetic wave irradiators and a plurality of electromagnetic wave receivers may be arranged in pairs to correspond to each other to measure the characteristic information of the electromagnetic wave based on the locations of the thin film on the substrate.

The thin film monitoring apparatus may further include a susceptor for seating the substrate thereon, and the susceptor may be movable in a direction parallel to an upper surface of the substrate to measure the characteristic information of the electromagnetic wave based on the locations of the thin film on the substrate.

The measurer may measure a transmittance or reflectance of the electromagnetic wave as the characteristic information of the electromagnetic wave.

The operation controller may calculate a carrier recombination time constant through inverse Laplace transform on a transmittance decay function of the electromagnetic wave over time, as a result using the measured characteristic information of the electromagnetic wave, and the carrier recombination time constant may be dividable by type of defects in the thin film and be inversely proportional to a defect density in the thin film.

The carrier recombination time constant may be dividable into a first carrier recombination time constant based on a first type of defects in the thin film and a second carrier recombination time constant based on a second type of defects in the thin film, the first carrier recombination time constant may be inversely proportional to a first defect density based on the first type of defects, the second carrier recombination time constant may be inversely proportional to a second defect density based on the second type of defects, and a size relationship between the first and second carrier recombination time constants may be opposite to a size relationship between the first and second defect densities in the thin film.

The thin film monitoring apparatus may further include a display for visualizing and displaying the composition uniformity or defect distribution of the thin film based on the locations on the substrate.

The beam emitter may generate a femtosecond laser beam, and the electromagnetic wave irradiator may irradiate a terahertz wave.

### Advantageous Effects

According to the afore-described embodiments of the present invention, a thin film monitoring method and thin film monitoring apparatus capable of monitoring composition uniformity or defect distribution of a thin film based on locations on a substrate in a non-contact and non-destructive manner may be implemented.

However, the scope of the present invention is not limited to the above effect.

### DESCRIPTION OF THE DRAWINGS

FIG. 1 is a flowchart of a thin film monitoring method according to an embodiment of the present invention.

FIG. 2 is a block diagram of a thin film monitoring apparatus for performing a thin film monitoring method according to an embodiment of the present invention.

FIG. 3 is a diagram for describing a procedure of measuring recombination of free electrons over time by using a thin film monitoring method according to an embodiment of the present invention.

FIG. 4 is a graph showing how a transmittance of an electromagnetic wave decays over time in a thin film monitoring method according to an embodiment of the present invention.

FIG. 5 is a diagram showing a band structure based on the content of germanium (Ge).

FIG. 6 is a graph showing how free electrons recombine based on the content of Ge in a SiGe thin film.

FIGS. 7 to 9 are graphs showing results of measuring recombination of free electrons in substrates (e.g., Wafer A, Wafer B, and Wafer C) over time by using a method of applying optical pumping and then detecting a terahertz wave.

FIGS. 10 to 12 are graphs showing time constants divided through inverse Laplace transform based on defects in substrates in a thin film monitoring method according to an embodiment of the present invention.

FIGS. 13 to 16 are diagrams showing portions of thin film monitoring apparatuses according to various embodiments of the present invention.

### MODE OF THE INVENTION

Hereinafter, the present invention will be described in detail by explaining embodiments of the invention with reference to the attached drawings.

The invention may, however, be embodied in many different forms and should not be construed as being limited to the embodiments set forth herein; rather, these embodiments are provided so that this disclosure will be thorough and complete, and will fully convey the concept of the invention to one of ordinary skill in the art. In the drawings, the thicknesses or sizes of layers are exaggerated for clarity and convenience of explanation.

Embodiments of the invention are described herein with reference to schematic illustrations of idealized embodiments (and intermediate structures) of the invention. As such, variations from the shapes of the illustrations as a result, for example, of manufacturing techniques and/or tolerances, are to be expected. Thus, the embodiments of the invention should not be construed as limited to the particular shapes of regions illustrated herein, but are to include deviations in shapes that result, for example, from manufacturing.

The present invention relates to a thin film monitoring method for analyzing recombination of carriers optically excited using a femtosecond laser beam through time-resolved measurement of transmission or reflection of a terahertz wave to analyze composition uniformity and defect distribution of a semiconductor thin film on a substrate, and a thin film monitoring apparatus for performing the thin film monitoring method. The present invention also relates to a thin film monitoring method for analyzing composition uniformity or defect distribution of a thin film based on locations on a substrate by analyzing a recombination time constant change based on a defect density of carriers optically excited using a femtosecond laser beam through time-resolved measurement of transmission or reflection of a terahertz wave with respect to multiple points in the substrate, and a thin film monitoring apparatus for performing the thin film monitoring method.

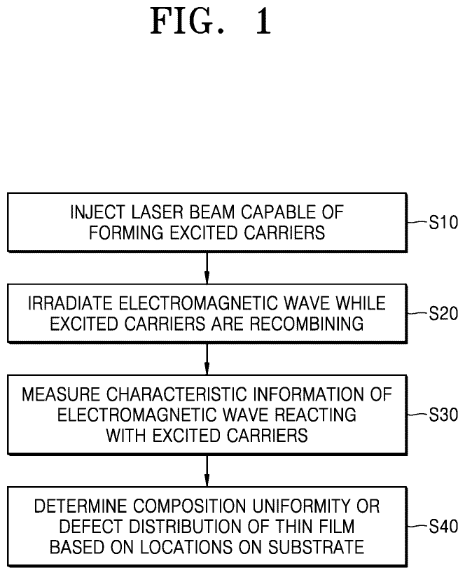

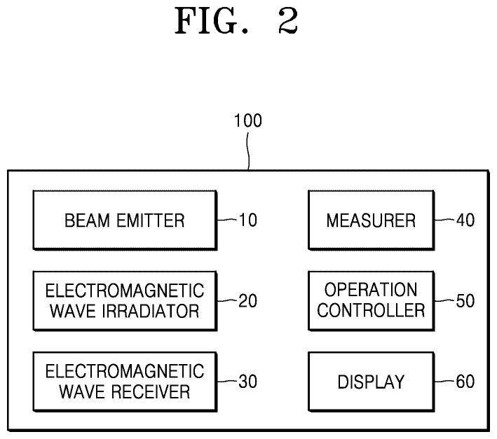

FIG. 1 is a flowchart of a thin film monitoring method according to an embodiment of the present invention, and FIG. 2 is a block diagram of a thin film monitoring apparatus for performing a thin film monitoring method according to an embodiment of the present invention.

Referring to FIG. 1, the thin film monitoring method according to an embodiment of the present invention includes injecting a laser beam into a thin film on a substrate to form excited carriers in the thin film (S10), irradiating an electromagnetic wave onto the thin film while the excited carriers in the thin film are recombining (S20), measuring characteristic information of the electromagnetic wave reacting with the excited carriers in the thin film (S30), and determining composition uniformity or defect distribution of the thin film based on locations on the substrate by using a parameter including the measured characteristic information of the electromagnetic wave (S40).

In the thin film monitoring method, the laser beam may include a femtosecond laser beam, and the electromagnetic wave may include a terahertz wave.

In the thin film monitoring method, the characteristic information of the electromagnetic wave may include a transmittance or reflectance of the electromagnetic wave. The parameter including the measured characteristic information of the electromagnetic wave may be a transmittance decay change of the electromagnetic wave over time or a carrier recombination time constant calculated through inverse Laplace transform on a transmittance decay function of the electromagnetic wave over time.

Referring to FIG. 2, a thin film monitoring apparatus 100 for performing the thin film monitoring method according to an embodiment of the present invention includes a beam emitter 10 for generating a beam to be injected into a thin film on a substrate to form excited carriers in the thin film, an electromagnetic wave irradiator 20 for irradiating an electromagnetic wave onto the thin film while the excited carriers in the thin film are recombining, an electromagnetic wave receiver 30 for receiving the electromagnetic wave transmitted through or reflected from the thin film, a measurer 40 for measuring characteristic information of the electromagnetic wave received by the electromagnetic wave receiver 30, and an operation controller 50 for determining composition uniformity or defect distribution of the thin film based on locations on the substrate by using a parameter including the measured characteristic information of the electromagnetic wave. The thin film monitoring apparatus 100 may further include a display 60 for visualizing and displaying the composition uniformity or defect distribution of the thin film based on the locations on the substrate, which is determined by the operation controller 50.

Referring to FIGS. 1 and 2 together, in the thin film monitoring apparatus 100 for performing the thin film monitoring method according to an embodiment of the present invention, the beam emitter 10 may perform at least a portion of the step S10 for injecting the laser beam into the thin film on the substrate to form the excited carriers in the thin film, the irradiator 20 may perform at least a portion of the step S20 for irradiating the electromagnetic wave onto the thin film while the excited carriers in the thin film are recombining, the electromagnetic wave receiver 30 and the measurer 40 may perform at least a portion of the step S30 for measuring the characteristic information of the electromagnetic wave reacting with the excited carriers in the thin film, and the operation controller 50 may perform at least a portion of the step S40 for determining the composition uniformity or defect distribution of the thin film based on the locations on the substrate by using the parameter including the measured characteristic information of the electromagnetic wave.

Although the electromagnetic wave receiver 30 and the measurer 40 are described as separate elements in the thin film monitoring apparatus according to an embodiment of the present invention, in a modified embodiment, the electromagnetic wave receiver 30 and the measurer 40 may be provided as a single element with integrated functions thereof.

The steps of the thin film monitoring method according to an embodiment of the present invention will now be described in detail. Therefore, the following description and the description provided above in relation to FIGS. 1 and 2 may also be applied to the thin film monitoring apparatus 100 for performing the thin film monitoring method of the present invention.

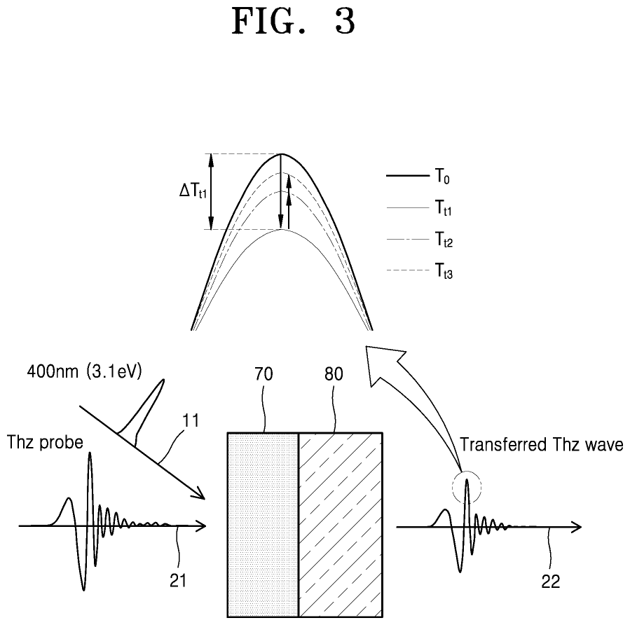

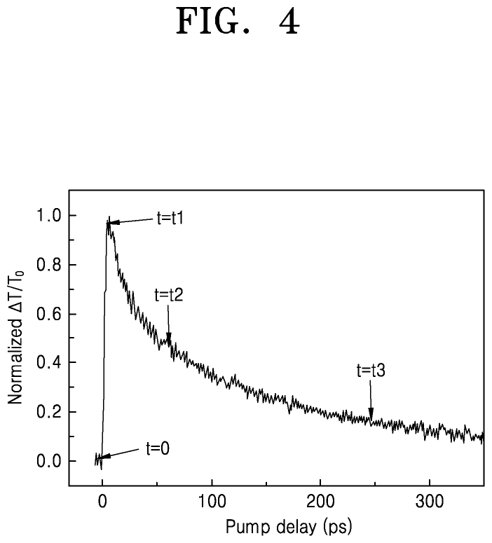

FIG. 3 is a diagram for describing a procedure of measuring recombination of free electrons over time by using a thin film monitoring method according to an embodiment of the present invention, and FIG. 4 is a graph showing how a transmittance of an electromagnetic wave decays over time in a thin film monitoring method according to an embodiment of the present invention.

In FIGS. 3 and 4, ΔT refers to a transmittance decay change of an electromagnetic wave (e.g., a terahertz wave), and T₀ refers to a transmittance of the electromagnetic wave when a laser beam for forming excited carriers is not injected into a thin film. “Pump delay” refers to a time elapsed from when the laser beam is injected into the thin film, and t=t1, t=t2, and t=t3 refer to timings at which the terahertz wave is irradiated after the laser beam is injected into the thin film.

Carriers (e.g., free electrons or holes) excited by a laser beam 11 injected into a thin film 70 formed on a substrate 80 recombine with a specific time constant through various paths. The laser beam injected into the thin film may be understood as a pump beam in that it forms excited carriers in the thin film.

In general, a recombination time constant based on a recombination path includes i) a recombination time constant based on an intra-valley scattering path (<ps), ii) a recombination time constant based on an inter-valley scattering path (to several ps), iii) a recombination time constant based on a defect-assisted recombination path (several ps to several ns), and iv) a recombination time constant based on an inter-band scattering path (hundreds of ps to μs).

Because the time constant of the defect-assisted recombination procedure is inversely proportional to a defect density of a material of the thin film 70, the defect density of the thin film 70 may be measured by analyzing the time constant of the recombination procedure.

In this case, to measure recombination of free electrons, for example, a terahertz wave may be used as an electromagnetic wave 21 or 22. For convenience of understanding, FIG. 3 separately shows a terahertz wave after being irradiated from a Thz probe of a beam emitter and before being transmitted through the thin film 70 (i.e., the electromagnetic wave 21), and a transferred Thz wave after being transmitted through the thin film 70 (i.e., the electromagnetic wave 22). The terahertz wave is an electromagnetic wave with a frequency of about 0.01 THz to 10 THz and is characterized in that it selectively reacts with free electrons. Therefore, by measuring changes in intensity of the terahertz wave transmitted through the material of the semiconductor thin film 70, the characteristics and quantity of free electrons inside the thin film 70 may be measured in a non-contact manner.

After a certain time is elapsed from when, for example, a femtosecond laser beam is injected as the laser beam 11 capable of forming excited carriers in the thin film, when a terahertz wave is transmitted as the electromagnetic wave 21 reacting with the excited carriers, a transmittance of the terahertz wave, i.e., the electromagnetic wave 22, is reduced by free electrons excited in the thin film 70 by the femtosecond laser beam. Therefore, the quantity of free electrons generated and recombined may be found out in a non-contact and non-destructive manner.

In this case, a recombination time constant of free electrons may be measured by measuring changes in transmittance of the terahertz wave over time after the femtosecond laser beam is injected, and thus a defect density of the thin film 70 constituting a semiconductor device may be measured in a non-contact and non-destructive manner.

When the excited free electrons recombine through multiple paths, the recombination time constant may be divided into time constants of free electrons recombining through different paths. Using this, when multiple types of defects contribute to defect-assisted recombination, densities of different types of defects may be independently measured by dividing the recombination time constant. That is, the carrier recombination time constant may be divided by type of defects in the thin film and be inversely proportional to a defect density in the thin film.

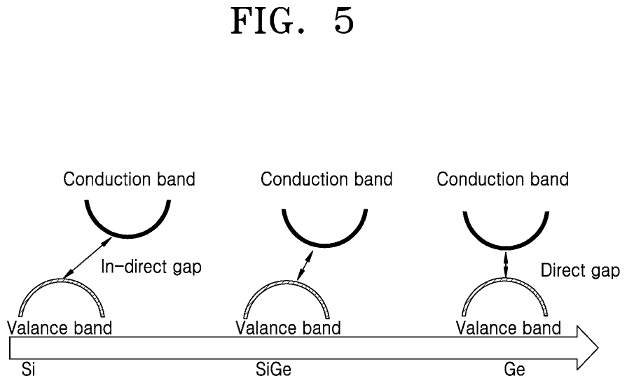

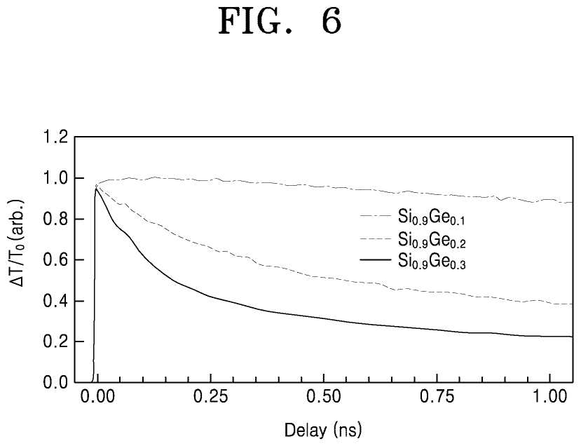

FIG. 5 is a diagram showing a band structure based on the content of germanium (Ge), and FIG. 6 is a graph showing how free electrons recombine based on the content of Ge in a SiGe thin film. “Delay” refers to a time elapsed from when a laser beam is injected into a thin film.

Referring to FIGS. 5 and 6, silicon (Si) has an indirect gap where the maximum energy value of the valence band and the minimum energy value of the conduction band occur at different momentum values, and germanium (Ge) has a direct gap where the maximum energy value of the valence band and the minimum energy value of the conduction band occur at the same momentum value. Si has a slow inter-band transition and Ge has a fast inter-band transition. When the concentration of Ge increases, SiGe gradually transitions from the indirect gap to the direct gap and thus the inter-band transition becomes faster.

Therefore, the concentration of Ge may be determined based on the quantity of remaining carriers at a time of a nanosecond (ns) or longer, which has a long time constant. Referring to FIG. 6 showing a transmittance change of a terahertz wave THz over time after optical pumping based on the content of Ge, it is shown that, when the content of Ge is higher, the transmittance change value is smaller (i.e., the quantity of excited carriers is less) at about 1 ns.

Using this, by applying optical pumping to different locations of a thin film on a substrate and then measuring changes in transmittance or reflectance of a terahertz wave THz over time, composition uniformity or defect distribution of the thin film based on locations on the substrate may be determined.

Optical pumping was applied to different locations of a thin film formed on a substrate (e.g., a 300 mm wafer) through chemical vapor deposition (CVD) and then transmittances of a terahertz wave THz over time were measured, and the transmittances were compared to previous results measured using atomic force microscopy (AFM), Hall effect measurement, and spectroscopic ellipsometry (SE).

Table 1 shows thin film properties measured using existing measurement methods.

TABLE 1

| | | Hall Effect | | |
|---|---|---|---|---|
| | AFM | Carrier | | |
| | Roughness | Concentration | Mobility | SE |
| Sample | [nm] | [/cm³] | [cm²/V-s] | Ge (x) |
| Wafer A_Center | 0.142 | 7.12E+18 | 63.9 | 0.168 |
| Wafer A_Edge | 0.105 | 5.10E+18 | 67.8 | 0.181 |
| Wafer B_Center | 0.136 | 6.76E+18 | 57.3 | 0.201 |
| Wafer B_Edge | 0.124 | 8.37E+18 | 50.3 | 0.266 |
| Wafer C_Center | 0.773 | 4.62E+18 | 55.9 | 0.242 |
| Wafer C_Edge | 0.703 | 6.74E+18 | 52.3 | 0.352 |

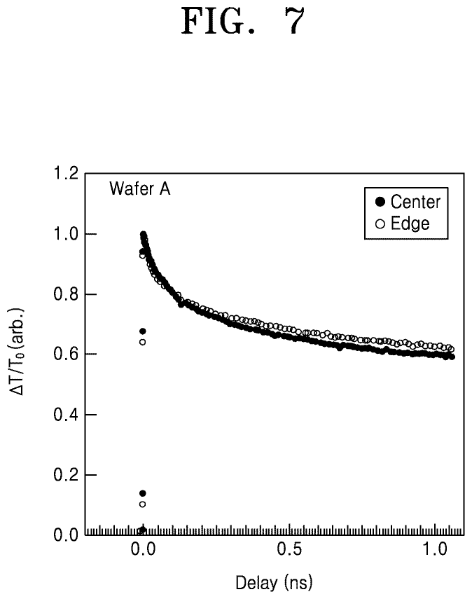

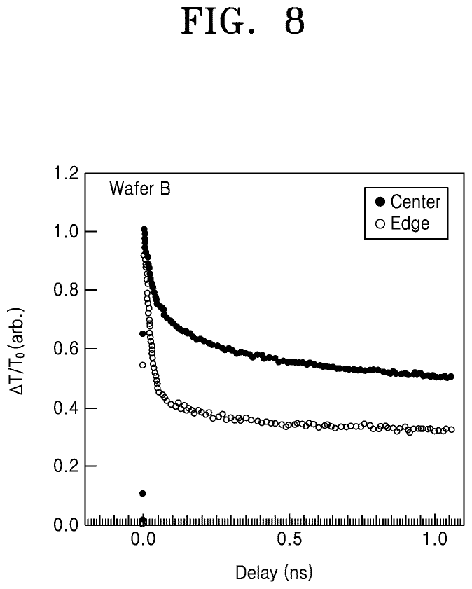

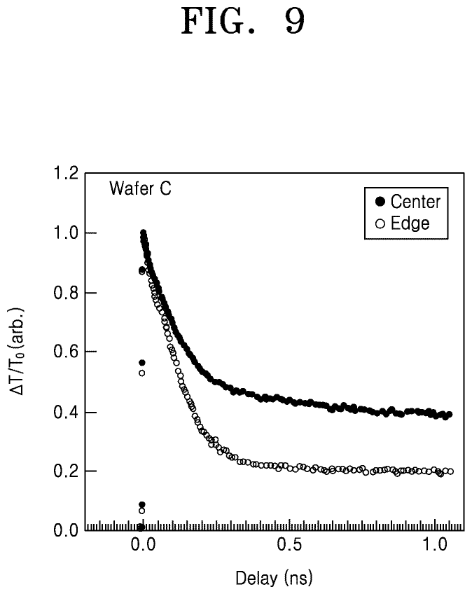

FIGS. 7 to 9 are graphs showing results of measuring recombination of free electrons in substrates (e.g., Wafer A, Wafer B, and Wafer C) over time by using a method of applying optical pumping and then detecting a terahertz wave. A 400-nm femtosecond laser beam was injected into a semiconductor thin film formed on a substrate (e.g., a 300 mm wafer), and then a transmittance change of a terahertz wave over time was measured. “Delay” refers to a time elapsed from when the laser beam is injected into the thin film.

Because carriers excited by the femtosecond laser beam recombine with various time constants depending on the composition or defects of the thin film, when carrier recombination data over time at different locations are measured and compared, composition uniformity or defect distribution of the thin film based on locations on the substrate may be determined. The locations on the substrate may include, for example, the center and the edge of the substrate.

Information about the composition may be determined based on the quantity of carriers which are excited near 1 ns and do not recombine, or changes in transmittance. In case of a thin film formed on a first substrate (e.g., Wafer A), similar transmittance changes of the terahertz wave over time were measured at the center and the edge and thus it may be determined that the composition of the thin film is uniform depending on location. However, in case of a thin film formed on a second substrate (e.g., Wafer B) and a thin film formed on a third substrate (e.g., Wafer C), quite different transmittance changes of the terahertz wave over time were measured at the center and the edge and thus it may be determined that the composition varies seriously depending on location.

According to results measured using spectroscopic ellipsometry (SE), the thin film formed on the first substrate (e.g., Wafer A) exhibits a small difference in composition between the center and the edge but the thin film formed on the second substrate (e.g., Wafer B) and the thin film formed on the third substrate (e.g., Wafer C) exhibit large differences in composition.

A relative ratio of defects in a semiconductor thin film at different locations may be obtained by precisely analyzing time constants through mathematical processing. Electrons excited by the laser beam recombine between hundreds of ps to change the transmittance of the terahertz wave over time and a decay of the transmittance over time in this case satisfies Equation 1 on the assumption that n types of defects are present.

$$\frac{Δ T}{{T}_{0}} ( t ) = {\sum }_{i = 1}^{n} {a}_{i} {e}^{- t / {τ}_{i}} \qquad [ Equation 1 ]$$

(ΔT: a transmittance decay change of an electromagnetic wave, T₀: a transmittance of the electromagnetic wave when a laser beam for forming excited carriers is not injected into a thin film, n: the number of defect types in the thin film, aᵢ: a carrier recombination contribution based on each type of defects in the thin film, t: time, and τᵢ: a carrier recombination time constant based on each type of defects)

When the composition of a semiconductor thin film is similar, the recombination time constant is inversely proportional to a defect density as shown in Equation 2.

$${τ}_{defect} ∝ \frac{1}{{N}_{defect}} \qquad [ Equation 2 ]$$

(N_{defect}: a defect density, and τ_{defect}: a recombination time constant by defects)

Therefore, the distribution in the substrate for a relative ratio of defect densities may be calculated for each type of defects through time constant analysis. Meanwhile, due to a subtle difference in defect density in the thin film, distinguishment may not be easily achieved only based on the decay tendencies. Mathematical processing may be adopted to distinguish time constants between similar decay signals.

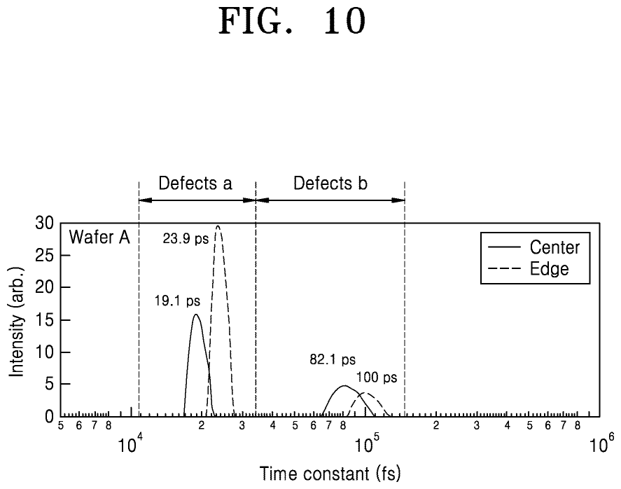

FIGS. 10 to 12 are graphs showing time constants divided through inverse Laplace transform based on defects in substrates in a thin film monitoring method according to an embodiment of the present invention.

In the present invention, it is found that a time-based decay function may be transformed into a time-constant-based function by using inverse Laplace transform and that a decay over time may be transformed into distribution of time constants shown in FIGS. 10 to 12.

A transmittance change curve of a terahertz wave over time occurs due to a plurality of decay factors. Because measurement data is brought when the influences of all decay factors are added together, a decay curve S(t) is expressed as the integral of a probability density F(k) multiplied by the decay function for all values of k (see Equation 3).

$$S ( t ) = {\int }_{0}^{∞} F ( k ) exp ( - kt ) dk \qquad [ Equation 3 ]$$

This is the same as the Laplace transform formula in form and inverse Laplace transform is required to calculate F(k) indicating the influence of the decay factors. Because F(k) may not be accurately calculated, a procedure of reducing an error rate by applying an approximation function is required and transform is performed by setting a margin of error rate based on a desired accuracy. As a result, an approximation of a time constant k and an approximation of the approximation function F(k) may be obtained, and F(k) may be considered as the influence of the decay factors. FIGS. 10 to 12 show a result of transforming a transmittance of a terahertz wave over time into a function related to a time constant by using inverse Laplace transform.

Table 2 shows a relative ratio of defect densities based on locations on a substrate, which is estimated by injecting a femtosecond laser beam and then measuring changes in transmittance or reflectance of a terahertz wave over time. That is, Table 2 shows a relative ratio of a defect density of the edge to the center.

TABLE 2

| | | Wafer A | | Wafer B | | Wafer C | |
|---|---|---|---|---|---|---|---|
| | | Center | Edge | Center | Edge | Center | Edge |
| Time | Defects a | 19.1 | 23.9 | 24.3 | 21.0 | 16.4 | 13.1 |
| Constant | Defects b | 82.1 | 100.0 | 153.0 | 332.0 | 96.7 | 99.5 |
| (ps) | | | | | | | |
| Relative | Defects a | 1.00 | 0.80 | 1.00 | 1.16 | 1.00 | 1.25 |
| Ratio of | Defects b | 1.00 | 0.82 | 1.00 | 0.46 | 1.00 | 0.97 |
| Defects | | | | | | | |

Referring to FIG. 10 and Tables 1 and 2 together, in case of the thin film formed on the first substrate (e.g., Wafer A), two types of defects (e.g., defects a and defects b) are present and defect densities of the first type of defects, i.e., defects a, and the second type of defects, i.e., defects b, are both higher at the center than at the edge. According to results measured through atomic force microscopy (AFM) and Hall effect measurement, the center has a higher carrier concentration, a lower mobility, and a higher roughness than the edge. Therefore, it may be determined that more defects are present at the center than at the edge.

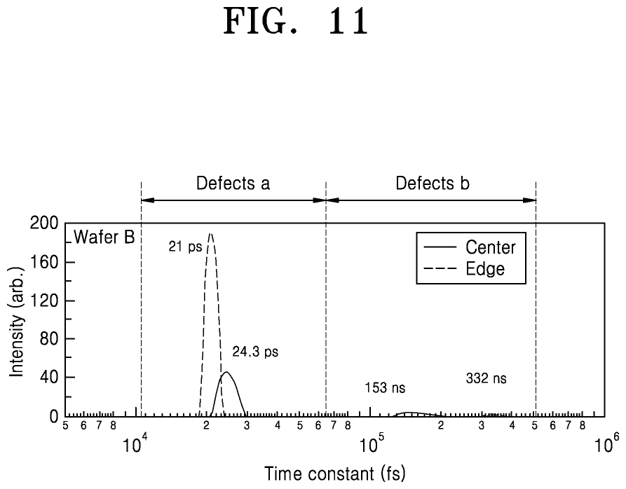

Referring to FIG. 11 and Tables 1 and 2 together, in case of the thin film formed on the second substrate (e.g., Wafer B), the center has a lower carrier concentration, a higher mobility, and a higher roughness than the edge. It is generally known that defects caused by addition or deletion of atoms increase carrier concentration and that structural defects (e.g., line defects) increase roughness. When recombination time constants of carriers excited using a femtosecond laser beam are analyzed, defects a are less at the center (e.g., a larger time constant) compared to the edge, and defects b are more at the center (e.g., a smaller time constant) compared to the edge. Therefore, in case of the thin film formed on the second substrate (e.g., Wafer B), defects a may be determined as defects related to addition or deletion of atoms, and defects b may be determined as defects related to structural defects (e.g., line defects).

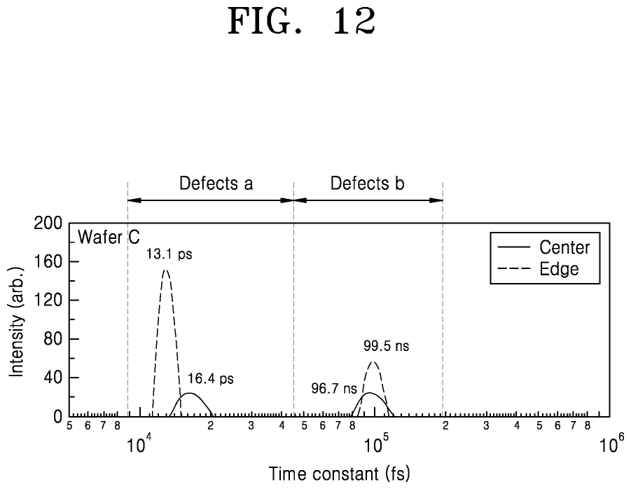

Referring to FIG. 12 and Tables 1 and 2 together, in case of the thin film formed on the third substrate (e.g., Wafer C), like the second substrate (e.g., Wafer B), the center has less defects a (e.g., a larger time constant) and more defects b (e.g., a smaller time constant). According to results of measuring the characteristics of the thin film formed on the third substrate (e.g., Wafer C), the center has a lower carrier concentration, a higher mobility, and a higher roughness compared to the edge.

Referring to Table 2, it is shown that a first carrier recombination time constant is inversely proportional to a first defect density based on a first type of defects, that a second carrier recombination time constant is inversely proportional to a second defect density based on a second type of defects, and that a size relationship between the first and second carrier recombination time constants is opposite to the size relationship between the first and second defect densities in the thin film.

The thin film monitoring method according to an embodiment of the present invention is described above on the assumption that the characteristic information of the electromagnetic wave includes a transmittance of the electromagnetic wave, and that the result using the measured characteristic information of the electromagnetic wave includes a carrier recombination time constant calculated through inverse Laplace transform on a transmittance decay function of the electromagnetic wave over time.

However, in a thin film monitoring method according to a modified embodiment of the present invention, the characteristic information of the electromagnetic wave may include a reflectance of the electromagnetic wave, and the result using the measured characteristic information of the electromagnetic wave may include a carrier recombination time constant calculated through inverse Laplace transform on a reflectance decay function of the electromagnetic wave over time. For example, ΔT of Equation 1 and FIGS. 4 and 6 to 9 may be replaced by a reflectance decay change ΔR of the electromagnetic wave, and T₀ of Equation 1 and FIGS. 4 and 6 to 9 may be replaced by a reflectance R₀ of the electromagnetic wave when the laser beam for forming excited carriers is not injected into the thin film. Furthermore, the configuration stating that the carrier recombination time constant is dividable by type of defects in the thin film and is inversely proportional to a defect density in the thin film, which is described above with reference to FIGS. 10 to 12, may be equally applied to a case in which the characteristic information of the electromagnetic wave is the reflectance of the electromagnetic wave as in the case in which the characteristic information of the electromagnetic wave is the transmittance of the electromagnetic wave.

Specific embodiments of thin film monitoring apparatuses for performing the above-described thin film monitoring method of the present invention will now be described.

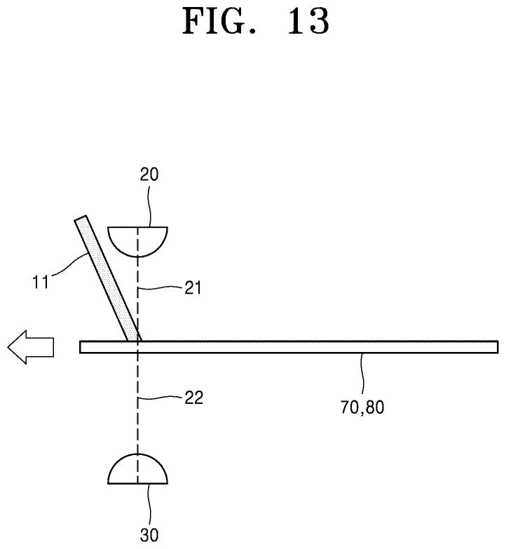

FIGS. 13 to 16 are diagrams showing portions of thin film monitoring apparatuses according to various embodiments of the present invention.

Referring to FIGS. 2 and 13, a thin film monitoring apparatus 100 according to a first embodiment of the present invention includes an electromagnetic wave irradiator 20 for irradiating an electromagnetic wave 21 onto the thin film 70 while carriers excited in the thin film 70 by the laser beam 11 are recombining, and an electromagnetic wave receiver 30 for receiving an electromagnetic wave 22 transmitted through the thin film 70. The electromagnetic wave irradiator 20 is located above the substrate 80, and the electromagnetic wave receiver 30 is located below the substrate 80 to receive the electromagnetic wave 22 transmitted through the thin film 70. The thin film monitoring apparatus 100 according to the first embodiment of the present invention may further include a susceptor for seating the substrate 80 thereon, and the susceptor may move in a direction parallel to an upper surface of the substrate 80 (i.e., an arrow direction in the drawing) to measure the characteristic information of the electromagnetic wave based on various locations of the thin film 70 on the substrate 80. For example, by moving the substrate 80 while the electromagnetic wave irradiator 20 and the electromagnetic wave receiver 30 are fixed with the above-described locational relationship, the characteristic information (e.g., a transmittance) of the electromagnetic wave with respect to the thin film may be measured at various locations (e.g., the center and the edge) on the substrate.

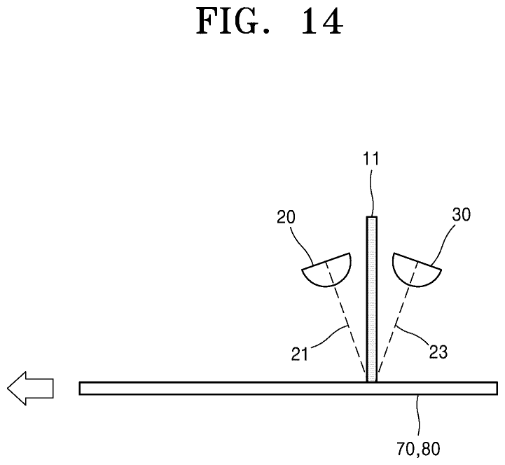

Referring to FIGS. 2 and 14, a thin film monitoring apparatus 100 according to a second embodiment of the present invention includes an electromagnetic wave irradiator 20 for irradiating an electromagnetic wave 21 onto the thin film 70 while carriers excited in the thin film 70 by the laser beam 11 are recombining, and an electromagnetic wave receiver 30 for receiving an electromagnetic wave 23 reflected from the thin film 70. The electromagnetic wave irradiator 20 is located above the substrate 80, and the electromagnetic wave receiver 30 is located above the substrate 80 to receive the electromagnetic wave 23 reflected from the thin film 70. The thin film monitoring apparatus 100 according to the second embodiment of the present invention may further include a susceptor for seating the substrate 80 thereon, and the susceptor may move in a direction parallel to an upper surface of the substrate 80 (i.e., an arrow direction in the drawing) to measure the characteristic information of the electromagnetic wave based on various locations of the thin film 70 on the substrate 80. For example, by moving the substrate 80 while the electromagnetic wave irradiator 20 and the electromagnetic wave receiver 30 are fixed with the above-described locational relationship, the characteristic information (e.g., a reflectance) of the electromagnetic wave with respect to the thin film may be measured at various locations (e.g., the center and the edge) on the substrate.

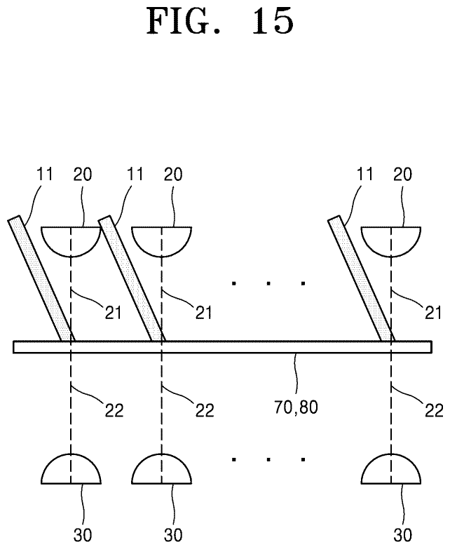

Referring to FIGS. 2 and 15, a thin film monitoring apparatus 100 according to a third embodiment of the present invention includes an electromagnetic wave irradiator 20 for irradiating an electromagnetic wave 21 onto the thin film 70 while carriers excited in the thin film 70 by the laser beam 11 are recombining, and an electromagnetic wave receiver 30 for receiving an electromagnetic wave 22 transmitted through the thin film 70. The electromagnetic wave irradiator 20 is located above the substrate 80, and the electromagnetic wave receiver 30 is located below the substrate 80 to receive the electromagnetic wave 22 transmitted through the thin film 70. In the thin film monitoring apparatus 100 according to the third embodiment of the present invention, to measure the characteristic information of the electromagnetic wave based on various locations of the thin film 70 on the substrate 80, a plurality of electromagnetic wave irradiators 20 and a plurality of electromagnetic wave receivers 30 may be arranged in pairs to correspond to each other. For example, by separately providing the pairs of electromagnetic wave irradiators 20 and electromagnetic wave receivers 30 at the center and the edge of the substrate 80, the characteristic information (e.g., a transmittance) of the electromagnetic wave with respect to the thin film may be measured at various locations (e.g., the center and the edge) on the substrate.

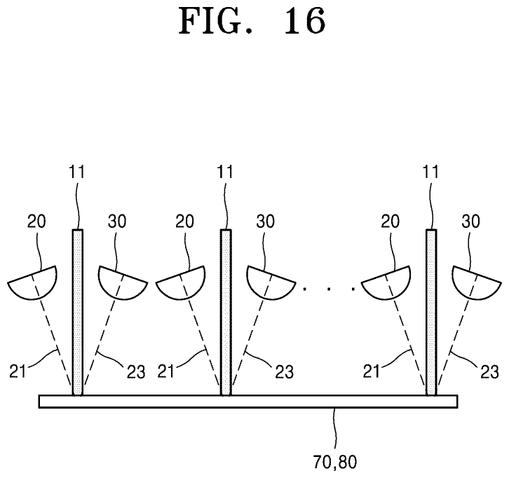

Referring to FIGS. 2 and 16, a thin film monitoring apparatus 100 according to a fourth embodiment of the present invention includes an electromagnetic wave irradiator 20 for irradiating an electromagnetic wave 21 onto the thin film 70 while carriers excited in the thin film 70 by the laser beam 11 are recombining, and an electromagnetic wave receiver 30 for receiving an electromagnetic wave 23 reflected from the thin film 70. The electromagnetic wave irradiator 20 is located above the substrate 80, and the electromagnetic wave receiver 30 is located above the substrate 80 to receive the electromagnetic wave 23 reflected from the thin film 70. In the thin film monitoring apparatus 100 according to the fourth embodiment of the present invention, to measure the characteristic information of the electromagnetic wave based on various locations of the thin film 70 on the substrate 80, a plurality of electromagnetic wave irradiators 20 and a plurality of electromagnetic wave receivers 30 may be arranged in pairs to correspond to each other. For example, by separately providing the pairs of electromagnetic wave irradiators 20 and electromagnetic wave receivers 30 at the center and the edge of the substrate 80, the characteristic information (e.g., a reflectance) of the electromagnetic wave with respect to the thin film may be measured at various locations (e.g., the center and the edge) on the substrate.

While the present invention has been particularly shown and described with reference to embodiments thereof, it will be understood by one of ordinary skill in the art that various changes in form and details may be made therein without departing from the scope of the present invention as defined by the following claims.

1. A thin film monitoring method comprising:
injecting a laser beam into a thin film on a substrate to form excited carriers in the thin film;
irradiating an electromagnetic wave onto the thin film while the excited carriers in the thin film are recombining;
measuring characteristic information of the electromagnetic wave reacting with the excited carriers in the thin film; and
determining composition uniformity or defect distribution of the thin film based on locations on the substrate by using a parameter comprising the measured characteristic information of the electromagnetic wave.

2. The thin film monitoring method of claim 1, wherein the characteristic information of the electromagnetic wave comprises a transmittance or reflectance of the electromagnetic wave.

3. The thin film monitoring method of claim 1, wherein the parameter comprising the measured characteristic information of the electromagnetic wave comprises a transmittance decay change of the electromagnetic wave over time.

4. The thin film monitoring method of claim 1, wherein the parameter comprising the measured characteristic information of the electromagnetic wave comprises a carrier recombination time constant calculated through inverse Laplace transform on a transmittance decay function of the electromagnetic wave over time.

5. The thin film monitoring method of claim 4, wherein the carrier recombination time constant is dividable by type of defects in the thin film and is inversely proportional to a defect density in the thin film.

6. The thin film monitoring method of claim 5, wherein the carrier recombination time constant is dividable into a first carrier recombination time constant based on a first type of defects in the thin film and a second carrier recombination time constant based on a second type of defects in the thin film.

7. The thin film monitoring method of claim 6, wherein the first carrier recombination time constant is inversely proportional to a first defect density based on the first type of defects, the second carrier recombination time constant is inversely proportional to a second defect density based on the second type of defects, and a size relationship between the first and second carrier recombination time constants is opposite to a size relationship between the first and second defect densities in the thin film.

8. The thin film monitoring method of claim 4, wherein the transmittance decay function of the electromagnetic wave over time is simulatable by Equation 1:
$$\frac{Δ T}{{T}_{0}} ( t ) = {\sum }_{i = 1}^{n} {a}_{i} {e}^{- t / {τ}_{i}} \qquad ( Equation 1 )$$
(ΔT: a transmittance decay change of the electromagnetic wave, T₀: a transmittance of the electromagnetic wave when the laser beam for forming excited carriers is not injected into the thin film, n: a number of defect types in the thin film, aᵢ: a carrier recombination contribution based on each type of defects in the thin film, t: time, and τᵢ: a carrier recombination time constant based on each type of defects).

9. The thin film monitoring method of claim 1, wherein the laser beam comprises a femtosecond laser beam, and the electromagnetic wave comprises a terahertz wave.

10. The thin film monitoring method of claim 1, wherein the excited carriers in the thin film comprise excited free electrons or holes in the thin film.

11. The thin film monitoring method of claim 1, wherein the locations on the substrate comprise a center and an edge of the substrate.

12. A thin film monitoring apparatus comprising:
a beam emitter for generating a beam to be injected into a thin film on a substrate to form excited carriers in the thin film;
an electromagnetic wave irradiator for irradiating an electromagnetic wave onto the thin film while the excited carriers in the thin film are recombining;
an electromagnetic wave receiver for receiving the electromagnetic wave transmitted through or reflected from the thin film;
a measurer for measuring characteristic information of the electromagnetic wave received by the electromagnetic wave receiver; and
an operation controller for determining composition uniformity or defect distribution of the thin film based on locations on the substrate by using a parameter comprising the measured characteristic information of the electromagnetic wave.

13. The thin film monitoring apparatus of claim 12, wherein the electromagnetic wave irradiator is located above the substrate, and the electromagnetic wave receiver is located below the substrate to receive the electromagnetic wave transmitted through the thin film.

14. The thin film monitoring apparatus of claim 12, wherein the electromagnetic wave irradiator is located above the substrate, and the electromagnetic wave receiver is located above the substrate to receive the electromagnetic wave reflected from the thin film.

15. The thin film monitoring apparatus of claim 13, wherein a plurality of electromagnetic wave irradiators and a plurality of electromagnetic wave receivers are arranged in pairs to correspond to each other to measure the characteristic information of the electromagnetic wave based on the locations of the thin film on the substrate.

16. The thin film monitoring apparatus of claim 12, further comprising a susceptor for seating the substrate thereon,
wherein the susceptor is movable in a direction parallel to an upper surface of the substrate to measure the characteristic information of the electromagnetic wave based on the locations of the thin film on the substrate.

17. The thin film monitoring apparatus of claim 12, wherein the measurer measures a transmittance or reflectance of the electromagnetic wave as the characteristic information of the electromagnetic wave.

18. The thin film monitoring apparatus of claim 12, wherein the operation controller calculates a carrier recombination time constant through inverse Laplace transform on a transmittance decay function of the electromagnetic wave over time, as a result using the measured characteristic information of the electromagnetic wave, and the carrier recombination time constant is dividable by type of defects in the thin film and is inversely proportional to a defect density in the thin film.

19. The thin film monitoring apparatus of claim 18, wherein the carrier recombination time constant is dividable into a first carrier recombination time constant based on a first type of defects in the thin film and a second carrier recombination time constant based on a second type of defects in the thin film, the first carrier recombination time constant is inversely proportional to a first defect density based on the first type of defects, the second carrier recombination time constant is inversely proportional to a second defect density based on the second type of defects, and a size relationship between the first and second carrier recombination time constants is opposite to a size relationship between the first and second defect densities in the thin film.

20. The thin film monitoring apparatus of claim 12, further comprising a display for visualizing and displaying the composition uniformity or defect distribution of the thin film based on the locations on the substrate.
